(19) United States
(12) Patent Application Publication
(10) Pub. No.: US 2026/0341387 A1
(43) Pub. Date: Oct. 29, 2026

(54) DATA ACCESS METHOD AND STORAGE DEVICE

(71) Applicant: Hefei Kaimeng Technology Co., Ltd., Anhui (CN)

(72) Inventors: Yang Chen, Anhui (CN); Tsung-Lin Wu, Anhui (CN); Qiao ZHU, Anhui (CN); Zhi WANG, Anhui (CN); Yan ZHENG, Anhui (CN); Dongsheng GUAN, Anhui (CN)

(73) Assignee: Hefei Kaimeng Technology Co., Ltd., Anhui (CN)

(21) Appl. No.: 19/660,278

(22) Filed: Apr. 28, 2026

(30) Foreign Application Priority Data
Apr. 29, 2025 (CN) 202510554772.8

(51) Int. Cl. G11C 29/30

(52) U.S. Cl. CPC G11C 29/30

(57) ABSTRACT

Provided are a data access method and a storage device. The method includes the following. In response to a data access event, first check information is generated at a first verification position inside the storage device according to target data and first logical unit information corresponding to the target data. The data access event indicates storing the target data into the memory module or reading the target data from the memory module. According to the target data and second logical unit information corresponding to the target data, second check information is generated at a second verification position inside the storage device. The second verification position is different from the first verification position. According to the first check information and the second check information, a verification operation is performed to obtain a verification result. According to the verification result, an operation corresponding to the data access event is performed.

### CROSS-REFERENCE TO RELATED APPLICATION

This application claims the priority benefit of China application serial no. 202510554772.8, filed on Apr. 29, 2025. The entirety of the above-mentioned patent application is hereby incorporated by reference herein and made a part of this specification.

### BACKGROUND

### Technical Field

The disclosure relates to a field of storage technology, and more particularly, to a data access method and a storage device.

### Description of Related Art

With the development of technology, the application of storage devices including non-volatile memory modules (e.g., flash memory modules) has become increasingly widespread. In general, a host system instructs the storage device to read, store, or delete user data stored at a logical address by using an operation command along with the logical address (e.g., a logical block address). Most storage devices support error correction (e.g., decoding) for the user data to avoid accessing incorrect user data.

However, storage devices generally lack an integrity verification mechanism for logical addresses. Therefore, when there is an integrity issue with a logical address, accessing a memory module based on this logical address will result in an access error, thereby reducing operational stability of the storage device.

### SUMMARY

The disclosure provides a data access method and a storage device, which may improve the above-mentioned issues, thereby enhancing operational stability of the storage device.

An embodiment of the disclosure provides a data access method for a storage device. The storage device is connected to a host system. The storage device includes a memory module. The data access method includes the following. In response to a data access event, first check information is generated at a first verification position inside the storage device according to target data and first logical unit information corresponding to the target data. The data access event indicates storing the target data into the memory module or reading the target data from the memory module. According to the target data and second logical unit information corresponding to the target data, second check information is generated at a second verification position inside the storage device. The second verification position is different from the first verification position. According to the first check information and the second check information, a verification operation is performed to obtain a verification result. According to the verification result, an operation corresponding to the data access event is performed.

An embodiment of the disclosure further provides a storage device, including a connection interface, a memory module, and a memory controller. The connection interface is configured to connect to a host system. The memory controller is connected to the connection interface and the memory module. The memory controller is configured to: in response to a data access event, generate first check information at a first verification position inside the storage device according to target data and first logical unit information corresponding to the target data, in which the data access event indicates storing the target data into the memory module or reading the target data from the memory module; according to the target data and second logical unit information corresponding to the target data, generate second check information at a second verification position inside the storage device, in which the second verification position is different from the first verification position; according to the first check information and the second check information, perform a verification operation to obtain a verification result; and according to the verification result, perform an operation corresponding to the data access event.

### BRIEF DESCRIPTION OF THE DRAWINGS

FIG. 1 is a schematic view of a data storage system according to an embodiment of the disclosure.

FIG. 2 is a schematic view of a memory controller according to an embodiment of the disclosure.

FIG. 3 is a schematic view of managing a memory module according to an embodiment of the disclosure.

FIG. 4 is a schematic view of a memory control circuit including a first controller and a second controller according to an embodiment of the disclosure.

FIGS. 5 and 6 are schematic views of operation scenarios for a data write event according to an embodiment of the disclosure.

FIGS. 7 to 9 are schematic views of operation scenarios for a data read event according to an embodiment of the disclosure.

FIG. 10 is a flowchart of a data access method according to an embodiment of the disclosure.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

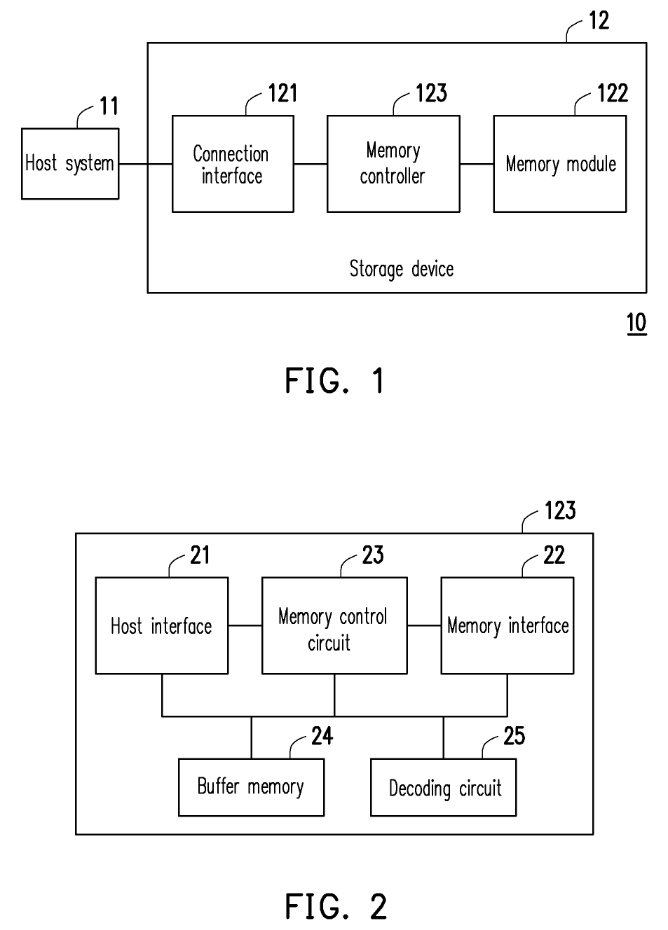

FIG. 1 is a schematic view of a data storage system according to an embodiment of the disclosure. Referring to FIG. 1, a data storage system 10 includes a host system 11 and a storage device 12. The storage device 12 may be connected to the host system 11 and may be used to store data from the host system 11. For example, the host system 11 may be a smartphone, a tablet computer, a notebook computer, a desktop computer, an industrial computer, a game console, a server, or a computer system installed in a specific carrier (e.g., a vehicle, an aircraft, or a vessel), and a type of the host system 11 is not limited thereto. In addition, the storage device 12 may include a solid-state drive, a USB flash drive, a memory card, or other types of non-volatile storage devices.

The storage device 12 includes a connection interface 121, a memory module 122, and a memory controller 123. The connection interface 121 is used to connect the storage device 12 to the host system 11. For example, the connection interface 121 may support an embedded multi-media card (eMMC), a universal flash storage (UFS), a peripheral component interconnect express (PCI Express), a non-volatile memory express (NVM express), a serial advanced technology attachment (SATA), a universal serial bus (USB), or other types of connection interface standards. Therefore, the storage device 12 may communicate with the host system 11 (e.g., exchange signals, commands, and/or data) via the connection interface 121.

The memory module 122 is used to store data. For example, the memory module 122 may include one or more rewritable non-volatile memory modules. Each of the rewritable non-volatile memory modules may include one or more memory cell arrays. Memory cells in the memory cell array store data in a form of voltages (also referred to as threshold voltages). For example, the memory module 122 may include a single level cell (SLC) NAND flash memory module, a multi level cell (MLC) NAND flash memory module, a triple level cell (TLC) NAND flash memory module, a quad level cell (QLC) NAND flash memory module, and/or other memory modules with the same or similar characteristics.

The memory controller 123 is connected to the connection interface 121 and the memory module 122. The memory controller 123 may be regarded as a control core of the storage device 12, and is used to control the storage device 12. For example, the memory controller 123 may be used to control or manage all or a part of operations of the storage device 12. For example, the memory controller 123 may include a central processing unit (CPU), or other programmable general-purpose or special-purpose microprocessors, digital signal processors (DSP), programmable controllers, application specific integrated circuits (ASIC), programmable logic devices (PLD), or other similar devices or combinations of these devices. In one embodiment, the memory controller 123 may include a flash memory controller.

The memory controller 123 may send a command sequence to the memory module 122 to access the memory module 122. For example, the memory controller 123 may send a write command sequence to the memory module 122 to instruct the memory module 122 to store data into specific memory cells. For example, the memory controller 123 may send a read command sequence to the memory module 122 to instruct the memory module 122 to read the data from the specific memory cells. For example, the memory controller 123 may send an erase command sequence to the memory module 122 to instruct the memory module 122 to erase the data stored in the specific memory cells. In addition, the memory controller 123 may further send other types of command sequences to the memory module 122 to instruct the memory module 122 to perform other types of operations, and the disclosure is not limited thereto. The memory module 122 may receive the command sequence from the memory controller 123 and access the memory cells inside the memory module 122 according to the command sequence.

FIG. 2 is a schematic view of a memory controller according to an embodiment of the disclosure. Referring to FIGS. 1 and 2, the memory controller 123 includes a host interface 21, a memory interface 22, and a memory control circuit 23. The host interface 21 is used to be connected to the host system 11 via the connection interface 121 to communicate with the host system 11. The memory interface 22 is used to be connected to the memory module 122 to access the memory module 122.

The memory control circuit 23 is connected to the host interface 21 and the memory interface 22. The memory control circuit 23 may be used to control or manage all or a part of operations of the memory controller 123. For example, the memory control circuit 23 may communicate with the host system 11 via the host interface 21 and access the memory module 122 via the memory interface 22. For example, the memory control circuit 23 may include control circuits such as an embedded controller or a microcontroller. In the following embodiments, the description of the memory control circuit 23 is equivalent to the description of the memory controller 123.

In one embodiment, the memory controller 123 may further include a buffer memory 24. The buffer memory 24 is connected to the memory control circuit 23 and is used to buffer data. For example, the buffer memory 24 may be used to buffer commands from the host system 11, data from the host system 11, and/or data from the memory module 122.

In one embodiment, the memory controller 123 may further include a decoding circuit 25. The decoding circuit 25 is connected to the memory control circuit 23 and is used to perform encoding and decoding on data to ensure correctness of the data. For example, the decoding circuit 25 may support various encoding/decoding algorithms such as a low density parity check code (LDPC code), a BCH code, a Reed-Solomon code (RS code), and an exclusive OR (XOR) code. In one embodiment, the memory controller 123 may further include other types of various circuit modules (e.g., a power management circuit, etc.), and the disclosure is not limited thereto.

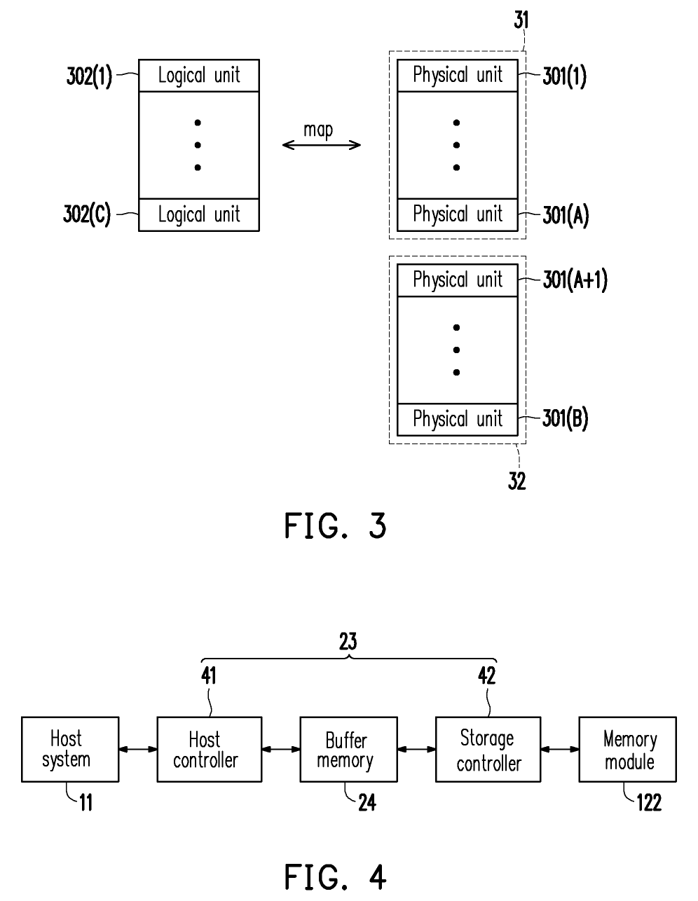

FIG. 3 is a schematic view of managing a memory module according to an embodiment of the disclosure. Referring to FIGS. 1 to 3, the memory module 122 includes multiple physical units 301(1) to 301(B). Each of the physical units includes multiple memory cells and is used to non-volatilely store data.

In one embodiment, one physical unit may include one or more physical programmed units. In one embodiment, one physical erase unit may include one or more physical programmed units.

In one embodiment, one physical programmed unit may include multiple physical sectors. For example, data capacity of one physical sector may be 512 bytes (B), and one physical programmed unit may include 32 physical sectors. However, the data capacity of one physical sector and/or the total number of physical sectors contained in one physical programmed unit may both be adjusted according to practical requirements, and the disclosure is not limited thereto. In one embodiment, one physical programmed unit may be regarded as one physical page. For example, storage capacity of one physical programmed unit may be 16 kilobytes, and the disclosure is not limited thereto.

In one embodiment, one physical programmed unit is a minimum unit for synchronously writing data in the memory module 122. For example, when a programming operation (also referred to as a write operation) is performed on one physical programmed unit to write data into the physical programmed unit, multiple memory cells in the physical programmed unit may be synchronously programmed to store the corresponding data. For example, when one physical programmed unit is programmed, a write voltage may be applied to the physical programmed unit to change a threshold voltage of at least some of the memory cells in the physical programmed unit. For example, the threshold voltage of one memory cell may reflect bit data stored in the memory cell.

In one embodiment, multiple physical programmed units in one physical erase unit may be synchronously erased. For example, when an erase operation is performed on one physical erase unit, an erase voltage may be applied to the physical programmed units in the physical erase unit to change the threshold voltage of at least some of the memory cells in the physical programmed units. By performing the erase operation on one physical erase unit, the data stored in the physical erase unit may be cleared. In one embodiment, one physical erase unit may be regarded as one physical block.

In one embodiment, the memory control circuit 23 may logically associate the physical units 301(1) to 301(A) and 301(A+1) to 301(B) with a data area 31 and an idle area 32, respectively. The physical units 301(1) to 301(A) in the data area 31 all store the data from the host system 11 (also referred to as user data). For example, any one of the physical units in the data area 31 may store valid data and/or invalid data. In addition, the physical units 301(A+1) to 301(B) in the idle area 32 do not store any data (e.g., the valid data).

In one embodiment, if a certain physical unit does not store the valid data, the physical unit may be associated with the idle area 32. In addition, the physical units in the idle area 32 may be erased to clear the data in the physical units. In one embodiment, the physical units in the idle area 32 are also referred to as idle physical units. In one embodiment, the idle area 32 is also referred to as a free pool.

In one embodiment, when the data is to be stored, the memory control circuit 23 may select one or more physical units from the idle area 32 and instruct the memory module 122 to store the data into the selected physical units. After the data is stored into the physical units, the physical units may be associated with the data area 31. In other words, one or more physical units may be alternately used between the data area 31 and the idle area 32.

In one embodiment, the memory control circuit 23 may be provided with multiple logical units 302(1) to 302(C) to map the physical units (i.e., the physical units 301(1) to 301(A)) in the data area 31. For example, one logical unit may correspond to one logical block address (LBA) or other logical management units. One logical unit may be mapped to one or more physical units.

In one embodiment, if a certain physical unit is currently mapped by any logical unit, the memory control circuit 23 may determine that the data currently stored in the physical unit includes the valid data. Conversely, if a certain physical unit is currently not mapped by any logical unit, the memory control circuit 23 may determine that the physical unit does not currently store any valid data.

In one embodiment, the memory control circuit 23 may record a mapping relationship between the logical units and the physical units in at least one management table (also referred to as a logical to physical mapping table). In one embodiment, the memory control circuit 23 may instruct the memory module 122 to perform operations such as data read, write, or erase according to information in the management table (i.e., the logical to physical mapping table).

In one embodiment, the memory control circuit 23 may detect a data access event. The data access event indicates access to specific data (also referred to as target data). For example, the data access event may be used to indicate storing the target data into the memory module 122, or reading the target data from the memory module 122.

In one embodiment, if the data access event is a data write event for the target data, the data access event may be used to indicate storing the target data into the memory module 122. Alternatively, in one embodiment, if the data access event is a data read event for the target data, the data access event may be used to indicate reading the target data from the memory module 122.

In one embodiment, in response to the data access event, the memory control circuit 23 may dynamically generate check information (also referred to as first check information) at a certain verification position (also referred to as a first verification position) inside the storage device 12 according to the target data and logical unit information corresponding to the target data (also referred to as first logical unit information). For example, the first logical unit information may reflect the logical unit to which the target data belongs (e.g., at least one of the logical units 302(1) to 302(C) in FIG. 3).

In one embodiment, at the first verification position, the memory control circuit 23 may perform a logical operation (also referred to as a first logical operation) on the target data and the first logical unit information to obtain the first check information. Alternatively, from another perspective, the first check information may reflect an operation result (also referred to as a first operation result) of performing the first logical operation on the target data and the first logical unit information.

In one embodiment, the first check information includes a cyclic redundancy check (CRC) code. For example, in the first logical operation, the memory control circuit 23 may input the target data and the first logical unit information into a cyclic redundancy check code generation algorithm to dynamically generate the first check information.

Thereafter, the first check information may be used to validate integrity of at least one of the target data and the logical unit information corresponding to the target data (e.g., the first logical unit information). In one embodiment, the first check information may further include other types of check information, as long as it conforms to the relevant descriptions of the embodiments of the disclosure.

In one embodiment, in response to the data access event, the memory control circuit 23 may further dynamically generate another check information (also referred to as second check information) at another verification position (also referred to as a second verification position) inside the storage device 12 according to the target data and another logical unit information corresponding to the target data (also referred to as second logical unit information). It should be noted that the second verification position is required to be different from the first verification position.

In one embodiment, at the second verification position, the memory control circuit 23 may perform a logical operation (also referred to as a second logical operation) on the target data and the second logical unit information to obtain the second check information. Alternatively, from another perspective, the second check information may reflect an operation result (also referred to as a second operation result) of performing the second logical operation on the target data and the second logical unit information.

In one embodiment, the second check information also includes the cyclic redundancy check (CRC) code. For example, in the second logical operation, the memory control circuit 23 may input the target data and the second logical unit information into the cyclic redundancy check code generation algorithm to dynamically generate the second check information. Thereafter, the second check information may be used to validate the integrity of at least one of the target data and the logical unit information corresponding to the target data (e.g., the second logical unit information). It should be noted that, in one embodiment, the second check information may further include other types of check information, as long as it conforms to the relevant descriptions of the embodiments of the disclosure.

In one embodiment, the storage device 12 may include multiple controllers. For example, the storage device 12 may include a first controller and a second controller. The first controller may be used to communicate with the host system 11.

For example, the first controller may be used to parse commands or signals from the host system 11 and may be used to transfer data to the host system 11. The second controller may be used to control the memory module 122. For example, the second controller may be used to control an access operation of the storage device 12 to the memory module 122. For example, the access operation includes a read operation, a write operation, an erase operation, or other operations, and the disclosure is not limited thereto.

In one embodiment, the first verification position is located at the first controller, and the second verification position is located at the second controller. That is, the first check information is dynamically generated by the first controller according to the target data and the first logical unit information. In addition, the second check information is dynamically generated by the second controller according to the target data and the second logical unit information.

In one embodiment, the first controller and the second controller may be simultaneously included in the memory control circuit 23 of FIG. 2. In one embodiment, the first controller is also referred to as a host controller, and/or the second controller is also referred to as a storage controller. In one embodiment, at least one of the first controller and the second controller may also be independent of the memory control circuit 23 of FIG. 2.

In one embodiment, after obtaining the first check information and the second check information, the memory control circuit 23 may perform a verification operation according to the first check information and the second check information to obtain a verification result. For example, the verification result may reflect an operating result of the verification operation. Then, the memory control circuit 23 may perform an operation corresponding to the aforementioned data access event according to the verification result.

In one embodiment, the verification operation is used to confirm whether the first check information is identical to the second check information. For example, the memory control circuit 23 may compare the first check information and the second check information to obtain the verification result. For example, the verification result may reflect whether the first check information is identical to the second check information.

In one embodiment, if the verification result indicates that the first check information is identical to the second check information, the memory control circuit 23 may determine that the verification result is a specific result (also referred to as a first result). In other words, the first result may reflect that the first check information is identical to the second check information.

In one embodiment, if the verification result indicates that the first check information is different from the second check information, the memory control circuit 23 may determine that the verification result is another result (also referred to as a second result). In other words, the second result may reflect that the first check information is different from the second check information.

In one embodiment, the first check information being identical to the second check information may refer to the cyclic redundancy check (CRC) code in the first check information being identical to the cyclic redundancy check (CRC) code in the second check information. In one embodiment, the first check information being different from the second check information may refer to the cyclic redundancy check (CRC) code in the first check information being different from the cyclic redundancy check (CRC) code in the second check information.

In one embodiment, the verification operation may also be used to confirm whether the first check information and the second check information meet a specific condition. For example, in one embodiment, if the first check information and the second check information meet the specific condition, the memory control circuit 23 may determine that the verification result is the first result. Alternatively, in one embodiment, if the first check information and the second check information do not meet the specific condition, the memory control circuit 23 may determine that the verification result is the second result.

In one embodiment, the first check information and the second check information meeting the specific condition may mean that after substituting the first check information and the second check information into a specific algorithm, an output of the specific algorithm meets expectations. In one embodiment, the first check information and the second check information not meeting the specific condition may mean that after substituting the first check information and the second check information into a specific algorithm, an output of the specific algorithm does not meet expectations.

In one embodiment, according to the verification result, the memory control circuit 23 may perform a default operation corresponding to the data access event, or perform error handling corresponding to the aforementioned data access event.

In one embodiment, if the data access event is the data write event for the target data and the verification result is the first result, the memory control circuit 23 may write the target data and the second logical unit information into the memory module 122 in response to a write command from the host system 11.

Alternatively, if the data access event is the data write event for the target data and the verification result is the second result, the memory control circuit 23 may perform error handling corresponding to the write command. For example, in the error handling corresponding to the write command, the memory control circuit 23 may send an error message to the host system 11 to notify the host system 11 that the write of the target data has failed.

In one embodiment, if the data access event is the data read event for the target data and the verification result is the first result, the memory control circuit 23 may transfer the target data read from the memory module 122 to the host system 11 in response to a read command from the host system 11.

Alternatively, if the data access event is the data read event for the target data and the verification result is the second result, the memory control circuit 23 may perform error handling corresponding to the read command. For example, in the error handling corresponding to the read command, the memory control circuit 23 may send an error message to the host system 11 to notify the host system 11 that the read of the target data has failed. In addition, implementation details of the aforementioned error handling may all be adjusted according to practical requirements.

In the following, multiple embodiments will be used to describe the operations performed respectively by the first controller and the second controller in the memory control circuit 23 when the data access event is the data write event or the data read event for the target data.

FIG. 4 is a schematic view of a memory control circuit including a first controller and a second controller according to an embodiment of the disclosure. Referring to FIG. 4, assume that the memory control circuit 23 includes a controller 41 (i.e., the first controller, also referred to as the host controller) and a controller 42 (i.e., the second controller, also referred to as the storage controller). The controller 41 may be used to communicate with the host system 11. The controller 42 may be used to control the memory module 122. In addition, both the controllers 41 and 42 may access the buffer memory 24. For example, both the controllers 41 and 42 may buffer data into the buffer memory 24, or read data from the buffer memory 24.

In one embodiment, the first verification position is located at the controller 41, and the second verification position is located at the controller 42. In this case, the first check information is dynamically generated by the controller 41 according to the target data and the first logical unit information. In addition, the second check information is dynamically generated by the controller 42 according to the target data and the second logical unit information.

Therefore, through the method provided by the above embodiments, the first check information and the second check information are calculated according to the target data and the first logical unit information/second logical unit information, and the first check information and the second check information are used for security verification. While ensuring accuracy of target data transmission and improving reliability of data transmission, correctness of the logical address may also be ensured, thereby ensuring the correspondence between the target data written into the storage device and the logical address.

In one embodiment, the first verification position is located at the controller 42, and the second verification position is located at the controller 41. In this case, the first check information is dynamically generated by the controller 42 according to the target data and the first logical unit information. In addition, the second check information is dynamically generated by the controller 41 according to the target data and the second logical unit information.

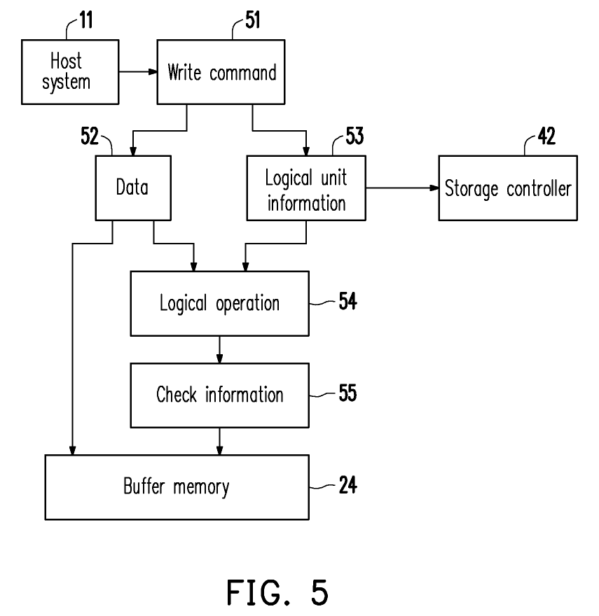

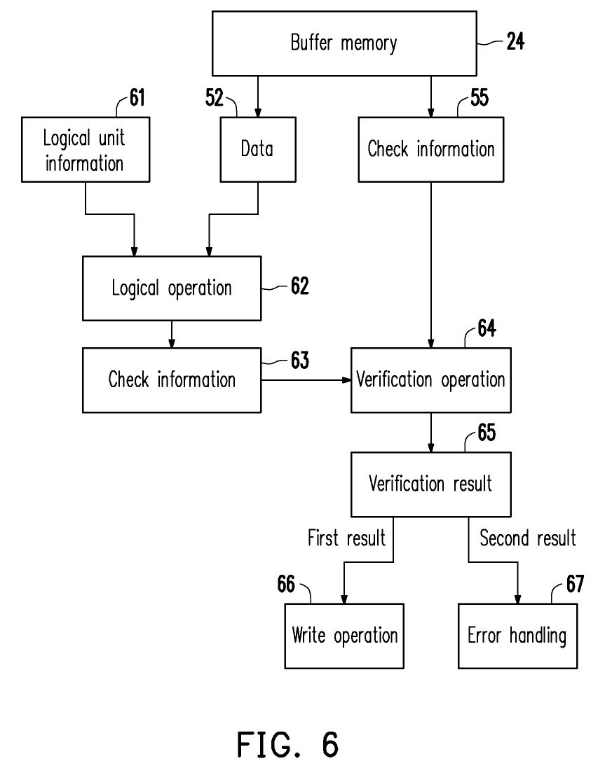

FIGS. 5 and 6 are schematic views of operation scenarios for a data write event according to an embodiment of the disclosure. Referring to FIG. 5, after obtaining a write command 51 corresponding to the data write event from the host system 11, the controller 41 may obtain data 52 (i.e., the target data) and logical unit information 53 (i.e., the first logical unit information) from the write command 51. For example, assume that the logical unit information 53 reflects a logical unit A, then the write command 51 may be used to instruct storing the data 52 belonging to logical unit A.

After obtaining the data 52 and the logical unit information 53, the controller 41 may perform a logical operation 54 (i.e., the first logical operation) on the data 52 and the logical unit information 53 to dynamically generate check information 55 (i.e., the first check information). The controller 41 may store the data 52 and the dynamically generated check information 55 into the buffer memory 24. In addition, the controller 41 may transfer the logical unit information 53 to the controller 42 as logical unit information 61 (i.e., the second logical unit information) in FIG. 6.

Referring to FIG. 6, continuing from the embodiment of FIG. 5, the controller 42 may obtain the logical unit information 61 according to the logical unit information 53 from the controller 41. In particular, information content of the logical unit information 61 may be the same as or different from information content of the logical unit information 53.

For example, in an ideal situation, the information content of the logical unit information 61 will be the same as the information content of the logical unit information 53. However, in a real situation, affected by channel noise, the information content of the logical unit information 61 may be different from the information content of the logical unit information 53. If the information content of the logical unit information 61 is different from the information content of the logical unit information 53, subsequent access operations (e.g., a write operation 66) performed on the memory module 122 based on the logical unit information 61 may result in execution failure or storage of incorrect data.

In one embodiment, the controller 42 may read the data 52 and the check information 55 from the buffer memory 24. The controller 42 may perform a logical operation 62 (i.e., the second logical operation) on the logical unit information 61 and the data 52 to dynamically generate check information 63 (i.e., the second check information). After generating the check information 63, the controller 42 may perform a verification operation 64 according to the check information 55 and the check information 63 to obtain a verification result 65.

In one embodiment, if the verification result 65 is the first result (e.g., the check information 55 is the same as the check information 63), the controller 42 may perform the write operation 66 in response to the write command 51. For example, in the write operation 66, the controller 42 may write the data 52 and the logical unit information 61 into the memory module 122.

However, in one embodiment, if the verification result 65 is the second result (e.g., the check information 55 is different from the check information 63), the controller 41 may perform error handling 67 corresponding to the write command 51. For example, in the error handling 67, the controller 41 may send an error message to the host system 11 to notify the host system 11 that the write of the data 52 has failed. Therefore, it may be ensured that the data (e.g., the data 52) finally written into the memory module 122 is indeed the data required by the write command 51, thereby effectively improving operational stability of the storage device 12.

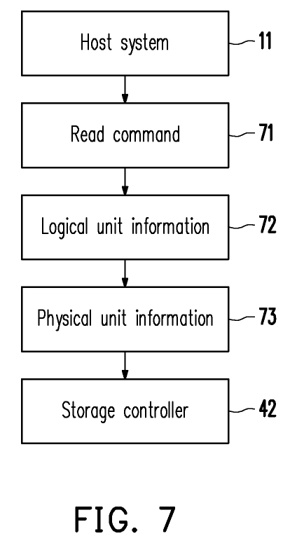

FIGS. 7 to 9 are schematic views of operation scenarios for a data read event according to an embodiment of the disclosure. Referring to FIG. 7, after obtaining a read command 71 corresponding to the data read event from the host system 11, the controller 41 may obtain logical unit information 72 (i.e., the first logical unit information) from the read command 71. For example, assume that the logical unit information 72 reflects a logical unit B, then the read command 71 may be used to instruct reading the data belonging to the logical unit B.

After obtaining the logical unit information 72, the controller 41 may obtain physical unit information 73 corresponding to the logical unit information 72. For example, the physical unit information 73 reflects a physical unit C, and the logical unit B is mapped to the physical unit C. For example, the controller 41 may query the management table (e.g., the logical to physical mapping table) according to the logical unit information 72 to obtain the physical unit information 73. Then, the controller 41 may transfer the physical unit information 73 to the controller 42.

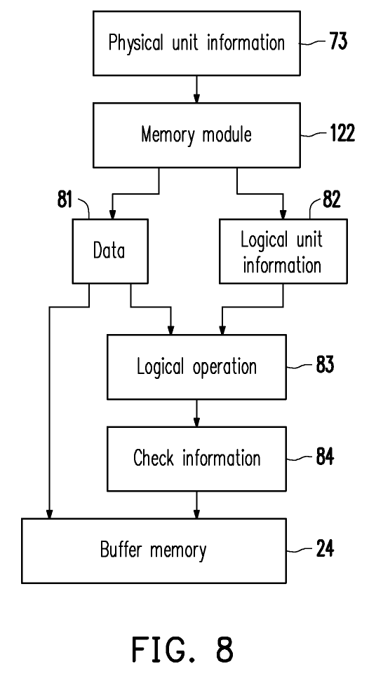

Referring to FIG. 8, continuing from the embodiment of FIG. 7, after obtaining the physical unit information 73, the controller 42 may access the memory module 122 according to the physical unit information 73 to obtain data 81 (i.e., the target data) and logical unit information 82 (i.e., the second logical unit information) from the memory module 122. The logical unit information 82 may reflect the logical unit to which the data 81 belongs. In particular, information content of the logical unit information 82 may be the same as or different from information content of the logical unit information 72.

For example, in an ideal situation, the information content of the logical unit information 82 will be the same as the information content of the logical unit information 72. However, in the real situation, affected by the channel noise, the information content of the logical unit information 82 may be different from the information content of the logical unit information 72. If the information content of the logical unit information 82 is different from the information content of the logical unit information 72, there is a high probability that the data 81 currently read is not the data truly instructed to be read by the read command 71. Therefore, if the information content of the logical unit information 82 is different from the information content of the logical unit information 72, a data read error may occur if the data 81 is transferred to the host system 11.

In one embodiment, after reading the data 81 and the logical unit information 82 from the memory module 122, the controller 42 may perform a logical operation 83 (i.e., the second logical operation) on the data 81 and the logical unit information 82 to dynamically generate check information 84 (i.e., the second check information). The controller 41 may store the data 81 and the dynamically generated check information 84 into the buffer memory 24.

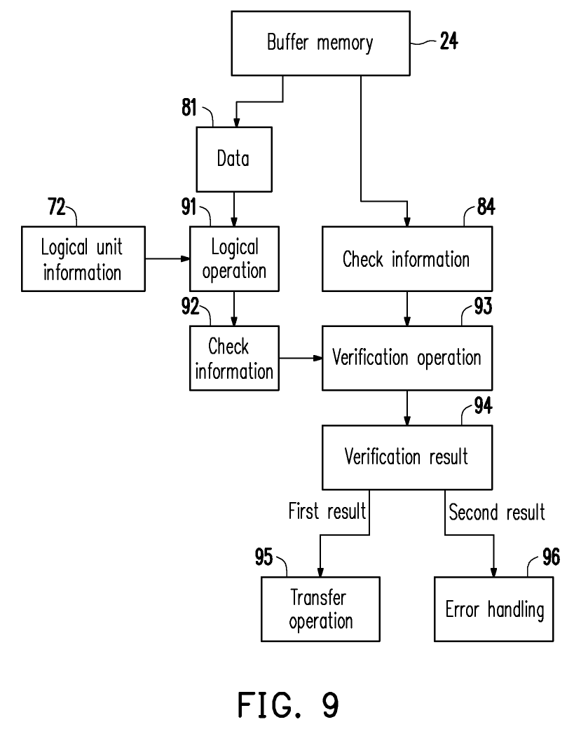

Referring to FIG. 9, continuing from the embodiment of FIG. 8, the controller 41 may obtain the data 81 and the dynamically generated check information 84 from the buffer memory 24. The controller 41 may perform a logical operation 91 (i.e., the first logical operation) on the logical unit information 72 and the data 81 to dynamically generate check information 92 (i.e., the first check information). After generating the check information 92, the controller 41 may perform a verification operation 93 according to the check information 92 and the check information 84 to obtain a verification result 94.

In one embodiment, if the verification result 94 is the first result (e.g., the check information 92 is the same as the check information 84), the controller 42 may perform a transfer operation 95 in response to the read command 71. For example, in the transfer operation 95, the controller 41 may transfer the data 81 to the host system 11 in response to the read command 71. However, in one embodiment, if the verification result 94 is the second result (e.g., the check information 92 is different from the check information 84), the controller 41 may perform error handling 96 corresponding to the write command 71. For example, in the error handling 96, the controller 41 may send an error message to the host system 11 to notify the host system 11 that the read of the data 81 has failed. Therefore, it may be ensured that the data (e.g., the data 81) finally transferred back to the host system 11 is indeed the data required by the read command 71, thereby effectively improving the operational stability of the storage device 12.

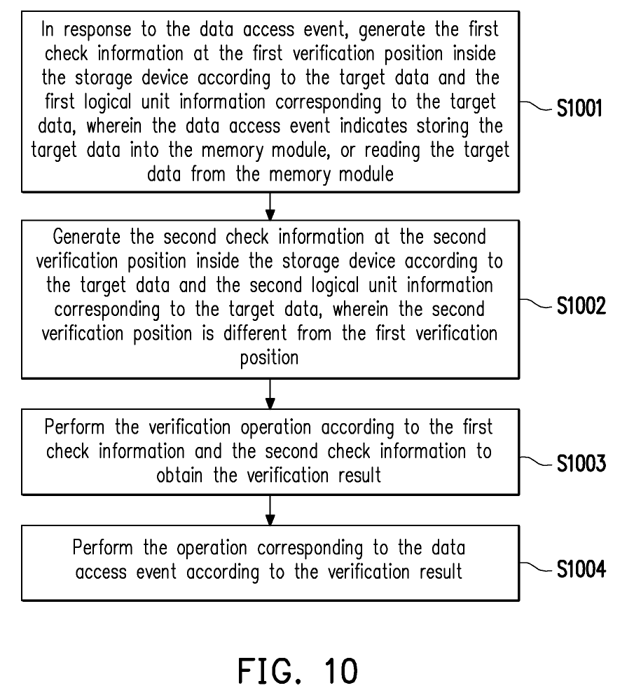

FIG. 10 is a flowchart of a data access method according to an embodiment of the disclosure. Referring to FIG. 10, in step S1001, in response to the data access event, the first check information is generated at the first verification position inside the storage device according to the target data and the first logical unit information corresponding to the target data. The data access event indicates storing the target data into the memory module, or reading the target data from the memory module.

In step S1002, the second check information is generated at the second verification position inside the storage device according to the target data and the second logical unit information corresponding to the target data. The second verification position is different from the first verification position.

In step S1003, the verification operation is performed according to the first check information and the second check information to obtain the verification result.

In step S1004, the operation corresponding to the data access event is performed according to the verification result.

However, the steps in FIG. 10 have been described in detail above and will not be repeated here. It is worth noting that the steps in FIG. 10 may be implemented as multiple program codes or circuits, and the disclosure is not limited thereto. In addition, the method of FIG. 10 may be used in conjunction with the above exemplary embodiments, or may be used alone, and the disclosure is not limited thereto.

Based on the above, the data access method and the storage device provided in the embodiments of the disclosure may allow the corresponding access operation to be performed only under the premise of ensuring that the logical unit information used by the storage device is consistent with the logical unit information indicated by the host system. Therefore, end-to-end access errors caused by inconsistency between the logical unit information used by the storage device and the logical unit information indicated by the host system (i.e., error detection or error correction not solely targeting the user data) may be reduced, thereby improving the operational stability of the storage device.

Finally, it should be noted that the above embodiments are only used to illustrate but not

to limit the technical solutions of the disclosure. Although the disclosure has been described in detail with reference to the foregoing embodiments, persons skilled in the art should understand that they may still modify the technical solutions described in the foregoing embodiments or equivalently replace some or all of the technical features. However, the modifications or replacements do not cause the spirit of the corresponding technical solution to deviate from the scope of the technical solution according to each embodiment of the disclosure.

What is claimed is:

1. A data access method for a storage device, wherein the storage device is connected to a host system, the storage device comprises a memory module, and the data access method comprises:
in response to a data access event, generating first check information at a first verification position inside the storage device according to target data and first logical unit information corresponding to the target data, wherein the data access event indicates storing the target data into the memory module or reading the target data from the memory module;
according to the target data and second logical unit information corresponding to the target data, generating second check information at a second verification position inside the storage device, wherein the second verification position is different from the first verification position;
according to the first check information and the second check information, performing a verification operation to obtain a verification result; and
according to the verification result, performing an operation corresponding to the data access event.

2. The data access method according to claim 1, wherein the storage device comprises a first controller and a second controller, the first verification position is located at the first controller, the second verification position is located at the second controller, the first controller is communicatively connected to the host system, and the second controller is configured to control the memory module.

3. The data access method according to claim 1, wherein the first check information reflects a first operation result of performing a first logical operation on the target data and the first logical unit information, and the second check information reflects a second operation result of performing a second logical operation on the target data and the second logical unit information.

4. The data access method according to claim 1, wherein the first check information and the second check information both comprise a cyclic redundancy check code.

5. The data access method according to claim 1, wherein the verification operation is configured to confirm whether the first check information is identical to the second check information.

6. The data access method according to claim 1, wherein according to the first check information and the second check information, performing the verification operation to obtain the verification result comprises:
comparing the first check information and the second check information to obtain the verification result.

7. The data access method according to claim 1, further comprising:
if the data access event is a data write event for the target data, obtaining the first logical unit information from a write command corresponding to the data write event by a first controller inside the storage device; and
transferring the first logical unit information to a second controller inside the storage device by the first controller to serve as the second logical unit information.

8. The data access method according to claim 7, wherein according to the verification result, performing the operation corresponding to the data access event comprises:
if the verification result is a first result, writing the target data and the second logical unit information into the memory module in response to the write command; and
if the verification result is a second result, performing error handling corresponding to the write command.

9. The data access method according to claim 1, further comprising:
if the data access event is a data read event for the target data, obtaining the first logical unit information from a read command corresponding to the data read event by a first controller inside the storage device;
obtaining physical unit information corresponding to the first logical unit information by the first controller; and
obtaining, by a second controller inside the storage device, the target data and the second logical unit information from the memory module according to the physical unit information.

10. The data access method according to claim 9, wherein according to the verification result, performing the operation corresponding to the data access event comprises:
if the verification result is a first result, transferring the target data to the host system in response to the read command; and
if the verification result is a second result, performing error handling corresponding to the read command.

11. A storage device, comprising:
a connection interface configured to connect to a host system;
a memory module; and
a memory controller connected to the connection interface and the memory module,
wherein the memory controller is configured to:
in response to a data access event, generate first check information at a first verification position inside the storage device according to target data and first logical unit information corresponding to the target data, wherein the data access event indicates storing the target data into the memory module or reading the target data from the memory module;
according to the target data and second logical unit information corresponding to the target data, generate second check information at a second verification position inside the storage device, wherein the second verification position is different from the first verification position;
according to the first check information and the second check information, perform a verification operation to obtain a verification result; and
according to the verification result, perform an operation corresponding to the data access event.

12. The storage device according to claim 11, wherein the memory controller comprises a first controller and a second controller, the first verification position is located at the first controller, the second verification position is located at the second controller, the first controller is configured to communicate with the host system, and the second controller is configured to control the memory module.

13. The storage device according to claim 11, wherein the first check information reflects a first operation result of performing a first logical operation on the target data and the first logical unit information, and the second check information reflects a second operation result of performing a second logical operation on the target data and the second logical unit information.

14. The storage device according to claim 11, wherein the first check information and the second check information both comprise a cyclic redundancy check code.

15. The storage device according to claim 11, wherein the verification operation is configured to confirm whether the first check information is identical to the second check information.

16. The storage device according to claim 11, wherein the operation of the memory controller performing the verification operation according to the first check information and the second check information to obtain the verification result comprises:
comparing the first check information and the second check information to obtain the verification result.

17. The storage device according to claim 11, wherein the memory controller is further configured to:
if the data access event is a data write event for the target data, obtain the first logical unit information from a write command corresponding to the data write event by a first controller inside the memory controller; and
transfer the first logical unit information to a second controller inside the memory controller by the first controller to serve as the second logical unit information.

18. The storage device according to claim 17, wherein according to the verification result, performing the operation corresponding to the data access event comprises:
if the verification result is a first result, writing the target data and the second logical unit information into the memory module in response to the write command; and
if the verification result is a second result, performing error handling corresponding to the write command.

19. The storage device according to claim 11, wherein the memory controller is further configured to:
if the data access event is a data read event for the target data, obtain the first logical unit information from a read command corresponding to the data read event by a first controller inside the storage device;
obtain physical unit information corresponding to the first logical unit information by the first controller; and
obtain, by a second controller inside the storage device, the target data and the second logical unit information from the memory module according to the physical unit information.

20. The storage device according to claim 19, wherein performing the operation corresponding to the data access event according to the verification result by the memory controller comprises:
if the verification result is a first result, transferring the target data to the host system in response to the read command; and
if the verification result is a second result, performing error handling corresponding to the read command.
